(19) United States
(12) Patent Application Publication
(10) Pub. No.: US 2022/0316817 A1
(43) Pub. Date: Oct. 6, 2022

(54) LIQUID-COOLING HEAT DISSIPATION STRUCTURE

(71) Applicant: ASIA VITAL COMPONENTS CO., LTD., New Taipei City (TW)

(72) Inventors: Sung-Wei Lee, New Taipei City (TW); Kuan-Lin Huang, New Taipei City (TW); Ming-Tsung Yang, New Taipei City (TW)

(21) Appl. No.: 17/216,712

(22) Filed: Mar. 30, 2021

(51) Int. Cl. F28F 3/04

(52) U.S. Cl. CPC F28F 3/048; F28F 2250/102

(57) ABSTRACT

A liquid-cooling heat dissipation structure includes a substrate and a cover body mated with the substrate to define a heat exchange chamber therebetween. A radiating fin unit and a stop section are disposed in the heat exchange chamber. The stop section serves to first divide a cooling liquid entering the heat exchange chamber, whereby the cooling liquid first flows through the periphery of the radiating fin unit and then flow into the middle of the radiating fin unit so that the cooling liquid is prevented from straightly passing through the radiating fin unit. Multiple cooperative flow-stopping protrusions are disposed in the periphery of the radiating fin unit to help the cooling liquid to uniformly flow through the radiating fin unit. By means of the structural design of the liquid-cooling heat dissipation structure, the heat exchange efficiency is greatly enhanced.

### BACKGROUND OF THE INVENTION

1. Field of the Invention

The present invention relates generally to the field of liquid heat dissipation structure, and more particularly to a heat dissipation structure of a liquid (water) block.

2. Description of the Related Art

Along with the great enhancement of the requirement for big data and cloud computing service, the requirement for heat dissipation of related electronic products has become higher and higher. Especially, with respect to the server of a large-scale operation center, the operation density is increased so that the waste heat generated in the space with the same size is greatly increased. In order to reduce the energy consumed in heat dissipation, recently, liquid-cooling structure is employed to carry away the heat from the server and then dissipate the heat in other manner. This can solve the problem of high-density waste heat.

The operation system of a water block or water plate is such that a working liquid carry away the heat of a chip. When passing through the chip, the temperature of the working liquid will gradually rise. Therefore, the temperature distribution of the chip is affected by the arrangement of the flow ways in the water plate. The temperature near the water inlet is lower, while the temperature near the water outlet is higher.

However, in the new-generation chip design, the heat generation area is increased so that the difference between the temperatures of the inlet and the outlet has become greater. This leads to non-uniform temperature distribution of the chip. The difference between the chip temperatures is so great that the lifetime of the chip is shortened. Moreover, after the working liquid enters the water block from the water inlet, the working liquid will directly quickly pass through the interior of the water block and then flow out from the water outlet. The retention time of the working liquid in the water block is so short that the working liquid contacts the radiating fins in the water block is very short. Under such circumstance, it is hard for the working liquid to fully carry away the heat by way of heat exchange.

It is therefore tried by the applicant to provide a liquid-cooling heat dissipation structure, which can solve the above problem and shortcoming existing in the conventional water block.

### SUMMARY OF THE INVENTION

It is therefore a primary object of the present invention to provide a liquid-cooling heat dissipation structure, in which a stop section is disposed between an inlet and a radiating fin unit in a heat exchange chamber. The stop section serves to divide a cooling liquid entering the heat exchange chamber from the inlet, whereby the cooling liquid first flows to the periphery of a radiating fin unit and then flows to the middle of the radiating fin unit. Therefore, the cooling liquid is prevented from straightly passing through the radiating fin unit.

It is a further object of the present invention to provide the above liquid-cooling heat dissipation structure, in which the flow field of the cooling liquid in the heat exchange chamber is uniformly distributed, whereby the temperature difference of the heat generation component is reduced so as to uniformly distribute the temperature.

It is still a further object of the present invention to provide the above liquid-cooling heat dissipation structure, in which multiple flow-stopping protrusions are disposed in the periphery of the radiating fin unit to distribute the cooling liquid of the periphery to the area necessitating heat dissipation so as to effectively reduce the temperature difference of the heat generation component.

It is still a further object of the present invention to provide the above liquid-cooling heat dissipation structure, which can prolong the retention time of the cooling liquid in the heat exchange chamber so as to ensure that the cooling liquid has sufficient time to fully and truly heat-exchange with the radiating fin unit.

It is still a further object of the present invention to provide the above liquid-cooling heat dissipation structure, in which multiple ribs are disposed in the heat exchange chamber. Each rib is positioned between each two adjacent radiating fin assemblies. The ribs serve to prevent the cooling liquid flowing through each radiating fin assembly from flowing to the other radiating fin assembly.

To achieve the above and other objects, the liquid-cooling heat dissipation structure of the present invention includes: a substrate having a heat exchange face and a heat contact face; a radiating fin unit including multiple radiating fin assemblies disposed on the heat exchange face, the radiating fin unit having a top face and two flow-in sides; a cover body connected and mated with the substrate above the radiating fin unit, a heat exchange chamber being defined between the substrate and the cover body to receive the radiating fin unit, the cover body having an inner face and a sidewall, the inner face having a guide channel corresponding to the top face of the radiating fin unit, a peripheral flow way set being defined between the radiating fin unit and the sidewall, an inlet and an outlet being respectively disposed on the cover body, the inlet being in communication with the heat exchange chamber, the outlet being in communication with the guide channel; and a stop section disposed in the heat exchange chamber and positioned between the inlet and the radiating fin unit to separate the inlet from the radiating fin unit. The stop section is in adjacency to the inlet, whereby a cooling liquid entering the heat exchange chamber from the inlet is divided to flow along the peripheral flow way to the middle of the radiating fin unit so that the cooling liquid is prevented from straightly passing through the radiating fin unit.

In the above liquid-cooling heat dissipation structure, multiple flow-stopping protrusions are disposed in the peripheral flow way set corresponding to the two flow-in sides of each radiating fin assembly.

In the above liquid-cooling heat dissipation structure, the peripheral flow way set includes a first peripheral flow way, a second peripheral flow way and a third peripheral flow way, the first and second peripheral flow ways being respectively defined between the flow-in sides and the sidewall, the third peripheral flow way being defined between the stop section and the sidewall corresponding to the inlet, whereby the cooling liquid in the peripheral flow ways flows from the flow-in sides to the middle of the radiating fin unit and then passes through the guide channel to flow out from the outlet.

In the above liquid-cooling heat dissipation structure, another radiating fin unit is selectively disposed in the third peripheral flow way.

In the above liquid-cooling heat dissipation structure, the flow-stopping protrusions are distributed over the first and second peripheral flow ways and disposed on the sidewall of the cover body or the heat exchange face of the substrate.

In the above liquid-cooling heat dissipation structure, a rib section is disposed between each two adjacent radiating fin assemblies, each rib section has a free end in contact with or in connection with the inner face of the cover body.

In the above liquid-cooling heat dissipation structure, the rib section has another free end connected with the heat exchange face of the substrate.

In the above liquid-cooling heat dissipation structure, the stop section is disposed on the heat exchange face of the substrate or the inner face of the cover body.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein:

Fig. 1A is a perspective exploded view of the present invention;

FIG. 1B is a perspective assembled view of the present invention;

FIG. 1C is a sectional assembled view of the present invention;

FIG. 2 is a top perspective view of the present invention;

FIG. 3 is a top perspective view of the present invention, showing that multiple flow-stopping protrusions are disposed in the heat exchange chamber; and

FIGS. 4A to 4C are schematic diagrams showing various flow-stopping protrusions with different configurations.

### DETAILED DESCRIPTION OF THE PREFERRED EMBODIMENTS

The present invention provides a liquid-cooling heat dissipation structure, for example, a liquid (water) block as a part of a liquid cooling loop. The liquid-cooling heat dissipation structure is in contact with a heat generation component to dissipate the heat of the heat generation component. The liquid-cooling heat dissipation structure is in communication with an external heat dissipation unit and/or pump via tube bodies. A stop section is disposed in a heat exchange chamber of the liquid-cooling heat dissipation structure so as to first divide the cooling liquid entering the heat exchange chamber. The divided cooling liquid flows to the periphery of a radiating fin unit and then flows to the middle of the radiating fin unit, whereby the cooling liquid is prevented from straightly passing through the radiating fin unit. Alternatively, multiple cooperative flow-stopping protrusions are disposed corresponding to the radiating fin unit to help the cooling liquid to uniformly flow through the radiating fin unit. The detailed structure of the present invention will be described hereinafter.

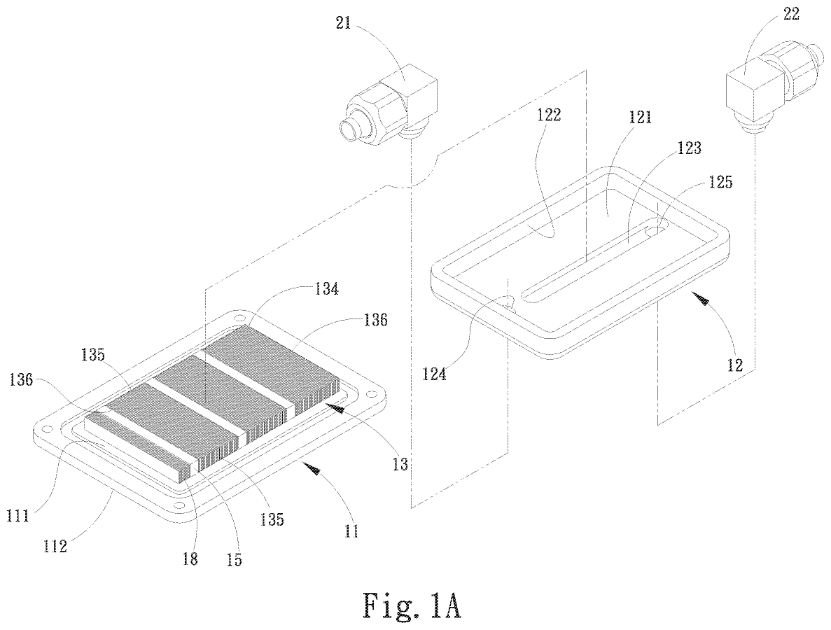

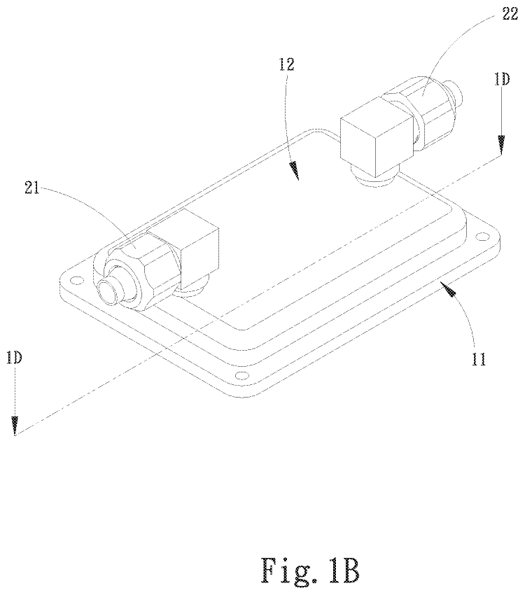

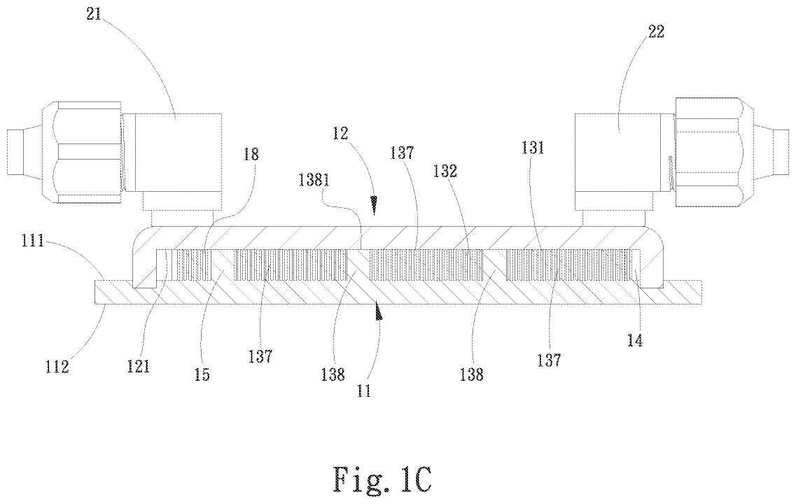

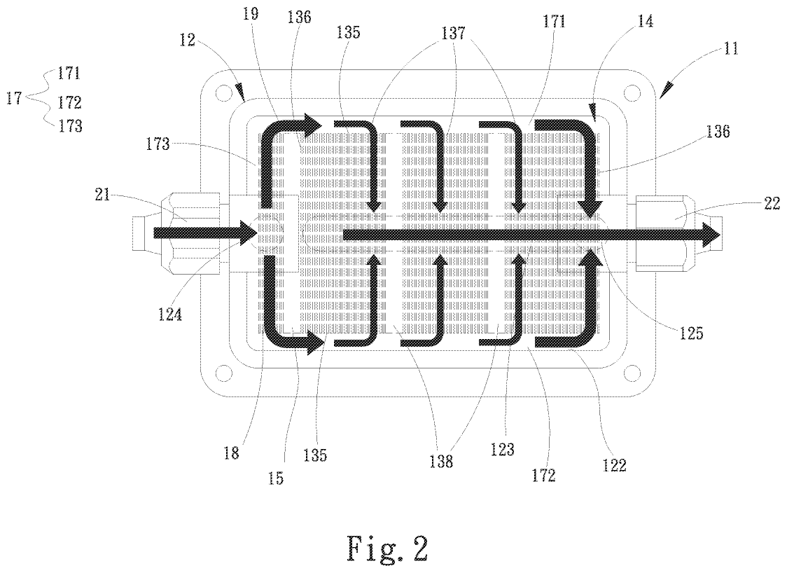

Please refer to FIGS. 1A to 2. Fig. 1A is a perspective exploded view of the present invention. FIG. 1B is a perspective assembled view of the present invention. FIG. 1C is a sectional assembled view of the present invention.

FIG. 2 is a top perspective view of the present invention. As shown in the drawings, the liquid-cooling heat dissipation structure of the present invention includes a substrate 11 and a cover body 12 mated with the substrate 11. A heat exchange chamber 14 is defined between the substrate 11 and the cover body 12 for a cooling liquid 19 to flow through. A stop section 15 is disposed in the heat exchange chamber 14. A radiating fin unit 13 is disposed in the heat exchange chamber 14. The substrate 11 has a heat exchange face 111 and a heat contact face 112. The cover body 12 has an inner face 121 and a sidewall 122. The inner face 121 faces the heat exchange face 111 of the substrate 11 and has a guide channel 123, an inlet 124 and an outlet 125 respectively disposed on the cover body 12. The inlet 124 is in communication with the heat exchange chamber 14.

The outlet 125 is in communication with the guide channel 123. The sidewall 122 is disposed along an outer periphery of the cover body 12 to connect with the substrate 11. A liquid incoming connector 21 and a liquid outgoing connector 22 are respectively connected with the inlet 124 and the outlet 125. The stop section 15 is disposed on the heat exchange face 111 of the substrate 11 or the inner face 121 of the cover body 12 and positioned behind the inlet 124. The stop section 15 serves to prevent the cooling liquid 19 from flowing from the inlet 124 into the heat exchange chamber 14 to directly flow through the radiating fin unit 13, whereby the cooling liquid 19 is divided into two flows to flow to two sides and then flow through the radiating fin unit 13. This will be more specifically described hereinafter.

The radiating fin unit 13 has multiple radiating fins 131 arranged at intervals. The radiating fins 131 define flow ways 132 therebetween. The radiating fin unit 13 has a top face 134, two flow-in sides 135 and two non-flow-in sides 136. The top face 134 is in adjacency to or in connection with the inner face 121 of the cover body 12 corresponding to the guide channel 123. The two flow-in sides 135 are opposite sides in communication with the flow ways 132 between the radiating fins 131.

The two non-flow-in sides 136 are also opposite sides in adjacency to the two flow-in sides 135. The radiating fin unit 13 is disposed or formed on the heat exchange face 111 of the substrate 11. That is, the radiating fin unit 13 is integrally formed or not integrally formed with the substrate 11. In addition, the two non-flow-in sides 136 are respectively in adjacency to the inlet 124 and the outlet 125 of the cover body 12. The stop section 15 is in adjacency to the inlet 124 and positioned between the inlet 124 and the non-flow-in sides 136 of the radiating fin unit 13.

Moreover, in this embodiment, the radiating fin unit 13 has multiple radiating fin assemblies 137. A rib section 138 is disposed between each two adjacent radiating fin assemblies 137. Each rib section 138 has a thickness thicker than the thickness of each single radiating fin 131. The radiating fin unit 13 and/or the rib sections 138 are integrally formed on the heat exchange face 111 of the substrate 11. Alternatively, the radiating fin unit 13 and/or the rib sections 138 are separate components and connected on the heat exchange face 111 of the substrate 11 by a connection means (such as welding including brazing, soldering and ultrasonic welding). Each rib section 138 has a free end (such as the upper end shown in the drawing) in adjacency to the inner face 121 of the cover body 12 or in contact with or in connection with the inner face 121.

A peripheral flow way set 17 is formed between the radiating fin unit 13 and the sidewall 122 around the radiating fin unit 13. The peripheral flow way set 17 includes a first peripheral flow way 171, a second peripheral flow way 172 and a third peripheral flow way 173. The first and second peripheral flow ways 171, 172 are respectively positioned between the flow-in sides 135 and the sidewall 122. The third peripheral flow way 173 is positioned between the stop section 15 and the sidewall 122 corresponding to the inlet 124. That is, the inlet 124 is positioned above the third peripheral flow way 173 and two ends of the third peripheral flow way 173 are respectively in communication with the first and second peripheral flow ways 171, 172. Another radiating fin unit 18 is, but not limited to, selectively disposed or formed in the third peripheral flow way 173 and positioned under the inlet 124. In the case that the heat generation area of the corresponding heat generation component is less, the radiating fin unit 18 in the third peripheral flow way 173 can be omitted.

The cooling liquid 19 passes through the liquid incoming connector 21 and flows from the inlet 124 of the cover body 12 into the third peripheral flow way 173 of the heat exchange chamber 14. The stop section 15 behind the inlet 124 prevents the cooling liquid 19 from straightly passing through the radiating fin unit 13. Therefore, the cooling liquid 19 is divided into two flows, which flow in reverse directions to respectively pass through two ends of the third peripheral flow way 173 into the first and second peripheral flow ways 171, 172. Then, the cooling liquid 19 in the first and second peripheral flow ways 171, 172 further flows from the two flow-in sides 135 of the radiating fin unit 13 into the middle of the radiating fin unit 13. Thereafter, the cooling liquid 19 passes through the guide channel 123 to flow out of the heat exchange chamber 14 from the outlet 125 and the liquid outgoing connector 22. The rib sections 138 serve to prevent the cooling liquid 19 flowing through each radiating fin assembly 137 from flowing to the other radiating fin assembly 137. According to the above arrangement, after divided, the cooling liquid 19 is not yet heated and can flow through all the radiating fin assemblies 137 at the same liquid temperature.

Furthermore, the stop section 15 prevents the cooling liquid 19 flowing into the heat exchange chamber 14 from straightly flowing through the radiating fin unit 13. Therefore, the retention time of the cooling liquid 19 in the heat exchange chamber 14 can be prolonged, whereby the cooling liquid 19 can fully heat-exchange with the radiating fin unit 13 to carry away the heat.

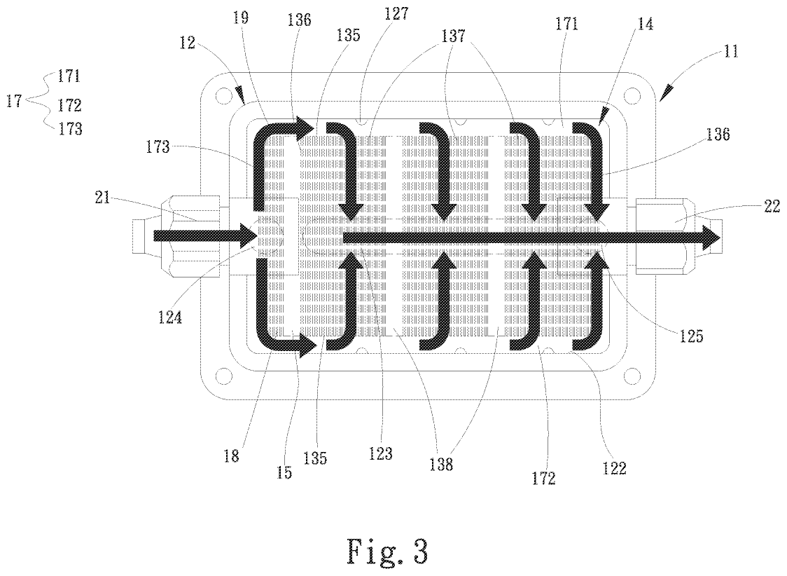

Please now refer to FIG. 3, which is a top perspective view of the present invention, showing that multiple flow-stopping protrusions are disposed in the heat exchange chamber. In a modified embodiment, multiple flow-stopping protrusions 127 are disposed in the peripheral flow way set 17. For example, the flow-stopping protrusions 127 are distributed over the first and second peripheral flow ways 171, 172 corresponding to the flow-in sides 135 of the radiating fin unit 13. Each radiating fin assembly 137 has at least two opposite corresponding flow-stopping protrusions 127.

In this embodiment, the flow-stopping protrusions 127 are, but not limited to, disposed on the sidewall 122 of the cover body 12. Alternatively, the flow-stopping protrusions 127 can be disposed on the heat exchange face 111 of the substrate 11. By means of the flow-stopping protrusions 127, the cooling liquid 19 flowing through the first and second peripheral flow ways 171, 172 is guided to flow to all the radiating fin assemblies 137 of the radiating fin unit 13, whereby the cooling liquid 19 can more uniformly flow within the liquid-cooling heat dissipation structure without collecting at the end of the flowing direction. In addition, without limitation of the above embodiment, according to different heat dissipation requirements, each radiating fin assembly 137 can have more corresponding opposite flow-stopping protrusions 127. Therefore, in design, the flow-stopping protrusions 127 can be arranged according to different temperatures of the respective heat generation areas of the heat generation component. For example, two opposite flow-stopping protrusions 127 are disposed in a low-temperature area, while four or more flow-stopping protrusions 127 are disposed in a high-temperature area.

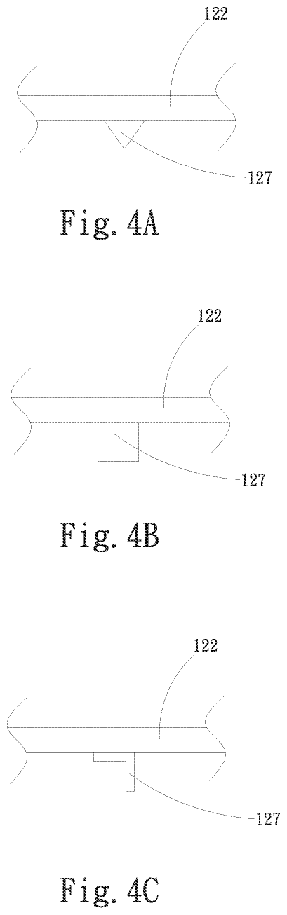

Please further refer to FIGS. 4A to 4C, which are schematic diagrams showing various flow-stopping protrusions with different configurations. The configuration of the flow-stopping protrusions 127 is not limited to semicircular shape. Alternatively, the configuration of the flow-stopping protrusions 127 can be triangular shape (as shown in FIG. 4A) or square shape (as shown in FIG. 4B) or L-shaped (as shown in FIG. 4C) or any other geometrical shape.

By means of the above structure, the flow field of the cooling liquid 19 entering the heat exchange chamber 14 is uniformly distributed, whereby the cooling liquid 19 can uniformly flow through the liquid-cooling heat dissipation structure to reduce the temperature difference of the heat generation component so as to uniformly distribute the temperature of the heat generation component.

The present invention has been described with the above embodiments thereof and it is understood that many changes and modifications in such as the form or layout pattern or practicing step of the above embodiments can be carried out without departing from the scope and the spirit of the invention that is intended to be limited only by the appended claims.

1. A liquid-cooling heat dissipation structure comprising:
a substrate having a heat exchange face and a heat contact face;
a radiating fin unit including multiple radiating fin assemblies disposed on the heat exchange face, the radiating fin unit having a top face and two flow-in sides;
a cover body connected and mated with the substrate above the radiating fin unit, a heat exchange chamber being defined between the substrate and the cover body to receive the radiating fin unit, the cover body having an inner face and a sidewall, the inner face having a guide channel corresponding to the top face of the radiating fin unit, a peripheral flow way set being defined between the radiating fin unit and the sidewall, an inlet and an outlet being respectively disposed on the cover body, the inlet being in communication with the heat exchange chamber, the outlet being in communication with the guide channel; and
a stop section disposed in the heat exchange chamber and positioned between the inlet and the radiating fin unit, the stop section being positioned behind the inlet, whereby a cooling liquid entering the heat exchange chamber from the inlet is divided to flow along the peripheral flow way to the middle of the radiating fin unit so that the cooling liquid is prevented from straightly passing through the radiating fin unit.

2. The liquid-cooling heat dissipation structure as claimed in claim 1, wherein multiple flow-stopping protrusions are disposed in the peripheral flow way set corresponding to the two flow-in sides of each radiating fin assembly.

3. The liquid-cooling heat dissipation structure as claimed in claim 1, wherein the peripheral flow way set includes a first peripheral flow way, a second peripheral flow way and a third peripheral flow way, the first and second peripheral flow ways being respectively defined between the flow-in sides and the sidewall, the third peripheral flow way being defined between the stop section and the sidewall corresponding to the inlet, whereby the cooling liquid in the peripheral flow ways flows from the flow-in sides to the middle of the radiating fin unit and then passes through the guide channel to flow out from the outlet.

4. The liquid-cooling heat dissipation structure as claimed in claim 3, wherein another radiating fin unit is selectively disposed in the third peripheral flow way.

5. The liquid-cooling heat dissipation structure as claimed in claim 3, wherein the flow-stopping protrusions are distributed over the first and second peripheral flow ways and disposed on the sidewall of the cover body or the heat exchange face of the substrate.

6. The liquid-cooling heat dissipation structure as claimed in claim 1, wherein the stop section is disposed on the heat exchange face of the substrate or the inner face of the cover body.
